(19) United States
(12) Patent Application Publication
(10) Pub. No.: US 2023/0352665 A1
(43) Pub. Date: Nov. 2, 2023

(54) POROUS SILICON-BASED CARBON COMPOSITE, METHOD FOR PREPARING SAME, AND NEGATIVE ELECTRODE ACTIVE MATERIAL COMPRISING SAME

(71) Applicant: DAEJOO ELECTRONIC MATERIALS CO., LTD., Siheung-si, Gyeonggi-do (KR)

(72) Inventors: Jeong Gyu PARK, Siheung-si, Gyeonggi-do (KR); Hyun Seok LEE, Siheung-si, Gyeonggi-do (KR); Young Min JEON, Siheung-si, Gyeonggi-do (KR); Seung Min OH, Siheung-si, Gyeonggi-do (KR); Heon Soo PARK, Siheung-si, Gyeonggi-do (KR); Sung Woo LIM, Siheung-si, Gyeonggi-do (KR); Hyun Hee LIM, Siheung-si, Gyeonggi-do (KR); Jong Chan LIM, Siheung-si, Gyeonggi-do (KR); Jung Hyun LEE, Siheung-si, Gyeonggi-do (KR)

(73) Assignee: DAEJOO ELECTRONIC MATERIALS CO., LTD., Siheung-si, Gyeonggi-do (KR)

(21) Appl. No.: 18/246,274

(22) PCT Filed: Sep. 17, 2021
(86) PCT No.: PCT/KR2021/012877

§ 371 Date: Mar. 22, 2023

(30) Foreign Application Priority Data
Sep. 23, 2020 (KR) 10-2020-0123353

(51) Int. Cl. H01M 4/36; H01M 4/583; H01M 4/38; H01M 4/04; H01M 4/58; H01M 10/052

(52) U.S. Cl. CPC H01M 4/366; H01M 4/583; H01M 4/386; H01M 4/0471; H01M 4/5825; H01M 4/364; H01M 10/052; H01M 2004/027

(57) ABSTRACT

An embodiment of the present invention relates to a porous silicon-based carbon composite, a method for preparing same, and a negative electrode active material comprising same. The porous silicon-based carbon composite according to an embodiment comprises silicon particles capable of intercalating and deintercalating lithium, a magnesium compound, and carbon, and satisfies a molar ratio (Mg/Si) of magnesium atoms to silicon atoms present in the composite of 0.02-0.30 and a molar ratio (O/Si) of oxygen atoms to silicon atoms in the composite of 0.40-0.90. Thus, when the porous silicon-based carbon composite is applied to a negative electrode active material, initial efficiency and capacity retention as well as discharge capacity can be enhanced.

### TECHNICAL FIELD

The present invention relates to a porous silicon-based-carbon composite, to a process for preparing the same, and to a negative electrode active material comprising the same.

### BACKGROUND ART

In recent years, as electronic devices become smaller, lighter, thinner, and more portable in tandem with the development of the information and communication industry, the demand for a high energy density of batteries used as power sources for these electronic devices is increasing. A lithium secondary battery is a battery that can best meet this demand, and research on small batteries using the same, as well as the application thereof to large electronic devices such as automobiles and power storage systems, is being actively conducted.

Carbon materials are widely used as a negative electrode active material for such a lithium secondary battery. Silicon-based negative electrode active materials are being studied in order to further enhance the capacity of batteries. Since the theoretical capacity of silicon (4,199 mAh/g) is greater than that of graphite (372 mAh/g) by 10 times or more, a significant enhancement in the battery capacity is expected.

The reaction scheme when lithium is intercalated into silicon is, for example, as follows:

22Li+5Si=Li₂₂Si₅ [Reaction Scheme 1]

In a silicon-based negative electrode active material according to the above reaction scheme, an alloy containing up to 4.4 lithium atoms per silicon atom with a high capacity is formed. However, in most silicon-based negative electrode active materials, volume expansion of up to 300% is induced by the intercalation of lithium, which destroys the negative electrode, making it difficult to exhibit high cycle characteristics.

In addition, this volume change may cause cracks on the surface of the negative electrode active material, and an ionic material may be formed inside the negative electrode active material, thereby causing the negative electrode active material to be electrically detached from the current collector. This electrical detachment phenomenon may significantly reduce the capacity retention rate of a battery.

In order to solve this problem, Japanese Patent No. 4393610 discloses a negative electrode active material in which silicon and carbon are mechanically processed to form a composite, and the surface of the silicon particles is coated with a carbon layer using a chemical vapor deposition (CVD) method.

In addition, Japanese Laid-open Patent Publication No. 2016-502253 discloses a negative electrode active material comprising porous silicon-based particles and carbon particles, wherein the carbon particles comprise fine carbon particles and coarse-grained carbon particles having different average particle diameters.

However, although these prior art documents relate to a negative electrode active material comprising silicon and carbon, there is a limit to suppressing volume expansion and contraction during charging and discharging. Thus, there is still a demand for research to solve these problems.

### PRIOR ART DOCUMENTS

### [Patent Documents]

(Patent Document 1) Japanese Patent No. 4393610

(Patent Document 2) Japanese Laid-open Patent Publication No. 2016-502253

(Patent Document 3) Japanese Laid-open Patent Publication No. 2018-0106485

### DETAILED DESCRIPTION OF THE INVENTION

### Technical Problem

The present invention is devised to solve the above problems of the prior art. A technical problem to be solved by the present invention is to provide a porous silicon-based-carbon composite in which the molar ratio of magnesium atoms to silicon atoms (Mg/Si) and the molar ratio of oxygen atoms to silicon atoms (O/Si) in the porous silicon-based-carbon composite satisfy specific ranges, respectively, whereby when it is applied to a negative electrode active material, the electrochemical properties of a lithium secondary battery, particularly excellent discharge capacity, are maintained while initial efficiency and lifespan characteristics in charge and discharge cycles are remarkably improved.

Another technical problem to be solved by the present invention is to provide a process for preparing the porous silicon-based-carbon composite.

Still another technical problem to be solved by the present invention is to provide a negative electrode active material comprising the porous silicon-based-carbon composite and a lithium secondary battery comprising the same.

### Solution to the Problem

In order to accomplish the above object, there is provided a porous silicon-based-carbon composite, which comprises silicon particles capable of absorbing and releasing lithium, a magnesium compound, and carbon, wherein the molar ratio of magnesium atoms to silicon atoms present in the composite (Mg/Si) is 0.02 to 0.30, and the molar ratio of oxygen atoms to silicon atoms present in the composite (O/Si) is 0.40 to 0.90.

Another embodiment provides a process for preparing the porous silicon-based-carbon composite, which comprises a first step of obtaining a silicon composite oxide powder using a silicon-based raw material and a magnesium-based raw material; a second step of etching the silicon composite oxide powder using an etching solution comprising a fluorine (F) atom-containing compound; a third step of filtering and drying the composite obtained by the etching to obtain a porous silicon composite; and a fourth step of forming a carbon layer on the surface of the porous silicon composite by using a chemical thermal decomposition deposition method.

Still another embodiment provides a negative electrode active material, which comprises the porous silicon-based-carbon composite.

Still another embodiment provides a lithium secondary battery comprising the negative electrode active material.

### Advantageous Effects of the Invention

The porous silicon-based-carbon composite according to the embodiment comprises silicon particles capable of absorbing and releasing lithium, a magnesium compound, and carbon, wherein the molar ratio of magnesium atoms to silicon atoms present in the composite (Mg/Si) is 0.02 to 0.30, and the molar ratio of oxygen atoms to silicon atoms present in the composite (O/Si) is 0.40 to 0.90, whereby when the porous silicon-based-carbon composite is applied to a negative electrode active material, the electrochemical properties of a lithium secondary battery, particularly excellent discharge capacity, are maintained while initial efficiency and lifespan characteristics in charge and discharge cycles are remarkably improved.

In addition, the process according to an embodiment has an advantage in that mass production is possible through a continuous process with minimized steps.

### BRIEF DESCRIPTION OF THE DRAWING

The following drawings attached to the present specification illustrate preferred embodiments of the present invention and serve to further understand the technical idea of the present invention together with the description of the present invention. Accordingly, the present invention should not be construed as being limited only to those depicted in the drawings.

FIG. 1a is a scanning electron microscope (FE-SEM) photograph of the silicon composite oxide powder prepared in Example 1. FIG. 1b is a field emission scanning electron microscopy (FE-SEM) photograph of the porous silicon composite prepared in Example 1 with respect to magnification.

FIGS. 2a to 2d are field emission scanning electron microscopy (FE-SEM) photographs of the surface of the porous silicon-based-carbon composite prepared in Example 1. They are shown in FIGS. 2a to 2d with respect to the magnification, respectively.

FIG. 3 is an ion beam scanning electron microscope (FIB-SEM) photograph of the porous silicon-based-carbon composite prepared in Example 1.

FIGS. 4a to 4c show the measurement results of an X-ray diffraction analysis of the silicon composite oxide (4a), porous silicon composite (4b), and porous silicon-based-carbon composite (4c) of Example 1.

FIG. 5 shows the measurement results of a Raman analysis of the porous silicon-based-carbon composite (c) of Example 1.

### BEST MODE FOR CARRYING OUT THE INVENTION

The present invention is not limited to what is disclosed below. Rather, it may be modified in various forms as long as the gist of the invention is not altered.

In this specification, when a part is referred to as “comprising” an element, it is to be understood that the part may comprise other elements as well, unless otherwise indicated.

In addition, all numbers and expressions related to the quantities of components, reaction conditions, and the like used herein are to be understood as being modified by the term “about,” unless otherwise indicated.

Porous silicon-based-carbon composite

The porous silicon-carbon composite according to an embodiment of the present invention comprises silicon particles capable of absorbing and releasing lithium, a magnesium compound, and carbon, wherein the molar ratio of magnesium atoms to silicon atoms present in the composite (Mg/Si) is 0.02 to 0.30, and the molar ratio of oxygen atoms to silicon atoms present in the composite (O/Si) is 0.40 to 0.90.

The porous silicon-based-carbon composite according to the embodiment comprises silicon particles capable of absorbing and releasing lithium, a magnesium compound, and carbon, wherein the molar ratio of magnesium atoms to silicon atoms present in the composite (Mg/Si) is 0.02 to 0.30, and the molar ratio of oxygen atoms to silicon atoms present in the composite (O/Si) is 0.40 to 0.90, whereby when the porous silicon-based-carbon composite is applied to a negative electrode active material, the electrochemical properties of a lithium secondary battery, particularly excellent discharge capacity, are maintained while initial efficiency and lifespan characteristics in charge and discharge cycles can be remarkably improved.

In general, due to the continuous reaction of a negative electrode active material comprising silicon particles with an electrolyte, a solid electrolyte interphase (SEI) layer, which is a non-conductive side reaction product layer, may be thickly formed on the surface of the negative electrode active material during charging and discharging. The negative electrode active material may be electrically shorted within the electrode due to the formation of a side reaction product layer, resulting in a problem of a decrease in lifespan characteristics and a further increase in volume expansion of the electrode.

Thus, it is necessary to reduce the reactivity between a negative electrode active material and an electrolyte to minimize the formation of a side reaction product layer that may be formed on the surface of the negative electrode active material.

Thus, according to an embodiment of the present invention, if the molar ratio of magnesium atoms to silicon atoms (Mg/Si) present in the porous silicon-carbon composite is adjusted to 0.02 to 0.30, and if the molar ratio of oxygen atoms to silicon atoms (O/Si) present in the composite is adjusted to 0.40 to 0.90, it does not act as a resistance during the lithium insertion reaction. As a result, when the composite is applied to a negative electrode active material, it is likely that there will be produced an effect that the electrochemical characteristics of the lithium secondary battery is not deteriorated.

In the porous silicon-based-carbon composite according to an embodiment of the present invention, silicon dioxide is removed through a selective etching process, whereby the acid number of silicon present in the surface layer of the porous silicon-based-carbon composite may be lowered. That is, it is preferable to adjust the molar ratio of oxygen atoms to silicon atoms (O/Si) within the above range by lowering the oxygen content of the porous silicon-based-carbon composite.

Specifically, the molar ratio of oxygen atoms to total silicon atoms (O/Si) present in the porous silicon-based-carbon composite may be 0.40 to 0.90, preferably, 0.40 to 0.80, even more preferably, 0.40 to 0.60.

In such a case, it is possible to significantly lower the oxygen fraction of the surface of the porous silicon-based-carbon composite and to reduce the surface resistance thereof. As a result, when the composite is applied to a negative electrode active material, the electrochemical properties, particularly, the initial efficiency and lifespan characteristics of a lithium secondary battery can be remarkably improved.

Specifically, a thin film composed of silicon oxide tends to be formed on the surface of a silicon particle. Since the surfaces of silicon particles can be easily oxidized, it is necessary to reduce the amount of oxygen in the silicon particles as much as possible. The lower the O/Si molar ratio, the more preferable. In such a case, since the active phase attributable to silicon increases, the initial efficiency of a secondary battery may be enhanced. Thus, according to an embodiment of the present invention, the adjustment of the molar ratio of oxygen atoms to total silicon atoms (O/Si) present in the porous silicon-based-carbon composite within a specific range would produce the above effect.

In addition, the molar ratio of magnesium atoms to silicon atoms (Mg/Si) present in the porous silicon-based-carbon composite may be 0.02 to 0.30, preferably, 0.03 to 0.30, even more preferably, 0.05 to 0.26.

As the molar ratio of Mg/Si present in the composite is adjusted to the above range, the oxygen fraction of the surface of the negative electrode active material is greatly lowered to reduce the surface resistance. As a result, when it is applied to a negative electrode active material, the electrochemical properties of a lithium secondary battery, particularly excellent discharge capacity, are maintained while initial efficiency and lifespan characteristics can be remarkably improved.

Hereinafter, each component of the porous silicon-based-carbon composite will be described in detail.

Silicon Particles

The porous silicon-based-carbon composite according to an embodiment of the present invention comprises silicon particles.

Since the silicon particles charge lithium, the capacity of a secondary battery may decrease if silicon particles are not employed. The silicon particles may be crystalline or amorphous and specifically may be amorphous or in a similar phase thereto. If the silicon particles are crystalline, as the size of the crystallites is small, the strength of the matrix may be fortified to prevent cracks. Thus, the initial efficiency or cycle lifespan characteristics of the secondary battery can be further enhanced. In addition, if the silicon particles are amorphous or in a similar phase thereto, expansion or contraction during charging and discharging of the lithium secondary battery is small, and battery performance such as capacity characteristics can be further enhanced.

Although the silicon particles have high initial efficiency and battery capacity, it is accompanied by a very complex crystal change by electrochemically absorbing, storing, and releasing lithium atoms.

When the porous silicon-based-carbon composite according to an embodiment of the present invention is subjected to an X-ray diffraction (Cu-Kα) analysis using copper as a cathode target and calculated by the Scherrer equation based on a full width at half maximum (FWHM) of the diffraction peak of Si (220) around 2θ=47.5°, the silicon particles may have a crystallite size of 1 nm to 20 nm, preferably, 1 nm to 15 nm, more preferably, 1 nm to 10 nm or 1 nm to 8 nm.

If the crystallite size of the silicon particles is 1 nm or more, it is possible to prevent the problem that the silicon particles escape through micropores inside the porous silicon-based-carbon composite. In addition, if the crystallite size is 20 nm or less, the micropores can adequately suppress the volume expansion of silicon particles that occur during charging and discharging, a region that does not contribute to discharging is hardly present, and a reduction in the Coulombic efficiency representing the ratio of charge capacity to discharge capacity can be suppressed.

As the silicon particles are made smaller to be atomized, a denser composite can be obtained, which can enhance the strength of the matrix. Accordingly, in such a case, the performance of a secondary battery such as discharge capacity, initial efficiency, or cycle lifespan characteristics may be further enhanced.

In addition, according to an embodiment of the present invention, the porous silicon-based-carbon composite may comprise a silicon aggregate in which the silicon particles are combined with each other.

Specifically, the porous silicon-based-carbon composite comprises silicon particles and may comprise a silicon aggregate having a three-dimensional (3D) structure in which two or more silicon particles are combined with each other. If the porous silicon-based-carbon composite comprises a silicon aggregate in which silicon particles are combined with each other, excellent mechanical properties such as strength can be obtained.

In addition, the porous silicon-based-carbon composite may further comprise a silicon oxide (SiOₓ, 0.1<x≤2) formed on the surface of the silicon particles or silicon aggregates. The silicon oxide (SiOₓ, 0.1<x≤2) may be formed by oxidation of the silicon.

In addition, the silicon particles contained in the porous silicon-based-carbon composite may further comprise an amorphous shape.

The content of silicon (Si) in the porous silicon-based-carbon composite may be 10% by weight to 90% by weight, preferably, 20% by weight to 80% by weight, more preferably, 30% by weight to 70% by weight, based on the total weight of the porous silicon-based-carbon composite.

If the content of silicon (Si) is less than 10% by weight, the amount of an active material for occlusion and release of lithium is small, which may reduce the charge and discharge capacity of the lithium secondary battery. On the other hand, if it exceeds 90% by weight, the charging and discharge capacity of the lithium secondary battery may be increased, whereas the expansion and contraction of the electrode during charging and discharging may be excessively increased, and the negative electrode active material powder may be further atomized, which may deteriorate the cycle characteristics.

Magnesium Compound

The porous silicon-based-carbon composite according to an embodiment of the present invention comprises a magnesium compound.

The magnesium compound may comprise magnesium silicate, fluorine-containing magnesium compound, or a mixture thereof.

Specifically, the magnesium compound may comprise magnesium silicate. The magnesium silicate may comprise a compound represented by the following Formula 1.

MgₓSiO_{y}(0.5≤x≤2, 2.5≤y≤4) [Formula 1]

Specifically, the magnesium silicate may comprise MgSiO₃ crystals, Mg₂SiO₄ crystals, or a mixture thereof. In particular, as the porous silicon-based-carbon composite comprises MgSiO₃ crystals, the Coulombic efficiency or capacity retention rate may be further increased.

The content of magnesium silicate may be 0.5 to 30% by weight, preferably, 0.5 to 25% by weight, more preferably, 0.5 to 20% by weight, based on the total weight of the porous silicon-based-carbon composite.

Meanwhile, since the silicon particles and the constituent elements of the MgSiO₃ crystal and/or the Mg₂SiO₄ crystal are diffused with each other, and the phase interface is in a bonded state, that is, each phase is in a bonded state at the atomic level, the change in volume is small when lithium ions are occluded and released, and cracks are hardly formed in the negative electrode active material even by repeated charging and discharging. Thus, capacity deterioration would hardly take place even with a high number of cycles. Thus, it is preferable that the MgSiO₃ crystals and/or Mg₂SiO₄ crystals are uniformly dispersed in the porous silicon-based-carbon composite. In addition, the crystallite size of the MgSiO₃ crystals and/or Mg₂SiO₄ crystals is preferably 10 nm or less, respectively.

In addition, the magnesium compound may comprise fluorine-containing magnesium compound.

In the porous silicon-based-carbon composite according to an embodiment of the present invention, magnesium silicate may be converted to fluorine-containing magnesium compound by etching.

In addition, some, most, or all of the magnesium silicate may be converted to fluorine-containing magnesium compound depending on the etching method or etching degree. More specifically, most of the magnesium silicate may be converted to fluorine-containing magnesium compound.

The preferable characteristics of the porous silicon-based-carbon composite that comprises fluorine-containing magnesium compound according to an embodiment of the present invention will be described below.

In general, silicon particles may occlude lithium ions during the charging of a secondary battery to form an alloy, which may increase the lattice constant and thereby expand the volume. In addition, during discharging of the secondary battery, lithium ions are released to return to the original metal nanoparticles, thereby reducing the lattice constant.

The fluorine-containing magnesium compound may be considered as a zero-strain lithium insertion material that does not accompany a change in the crystal lattice constant while lithium ions are occluded and released. The silicon particles may be present between the fluorine-containing magnesium compound particles and may be surrounded by the fluorine-containing magnesium compound particles.

In addition, the fluorine-containing magnesium compound does not release lithium ions during the charging of a lithium secondary battery. For example, it is also an inactive material that does not occlude or release lithium ions during the charging of a lithium secondary battery. In other words, it may be thought that fluorine-containing magnesium compound occludes lithium ions during the first (first time) charge, maintains the occluded state of lithium ions, and does not further occlude or release lithium ions during repeated charging and discharging thereafter.

Lithium ions are released from the silicon particles, whereas lithium ions, which have been steeply increased during charging, are not released from the fluorine-containing magnesium compound. Thus, a porous matrix comprising a fluorine-containing magnesium compound does not participate in the chemical reaction of the battery, but it is expected to function as a body that suppresses the volume expansion of silicon particles during the charging of the secondary battery.

The fluorine-containing magnesium compound may comprise magnesium fluoride (MgF₂), magnesium fluoride silicate (MgSiF₆), or a mixture thereof.

According to an embodiment of the present invention, the content of magnesium (Mg) may be 0.2% by weight to 15% by weight, preferably, 1.5% by weight to 10% by weight, more preferably, 2% by weight to 8% by weight, based on the total weight of the porous silicon-based-carbon composite.

If the content of magnesium (Mg) based on the total weight of the porous silicon-based-carbon composite is less than 0.2% by weight, there may be a problem in that the cycle characteristics of the secondary battery are reduced. If it exceeds 15% by weight, there may be a problem in that the charge capacity of the secondary battery is reduced.

In addition, it may have a structure in which silicon particles doped with magnesium (Mg) and coated with carbon are dispersed in the magnesium compound.

Since the magnesium compound hardly reacts with lithium ions during the charging and discharging of a secondary battery, it is possible to reduce the expansion and contraction of the electrode when lithium ions are occluded in the electrode, thereby enhancing the cycle characteristics of the secondary battery. In addition, the strength of the matrix, which is a continuous phase surrounding the silicon, can be fortified by the magnesium silicate.

Meanwhile, according to an embodiment of the present invention, the porous silicon-based-carbon composite may comprise a fluoride and/or silicate containing a metal other than magnesium. The other metals may be at least one selected from the group consisting of alkali metals, alkaline earth metals, Groups 13 to 16 elements, transition metals, rare earth elements, and combinations thereof. Specific examples thereof may include Li, Ca, Sr, Ba, Y, Ti, Zr, Hf, V, Nb, Cr, Mo, W, Fe, Pb, Ru, Ir, Pd, Pt, Cu, Ag, Au, Zn, Cd, B, Al, Ga, Sn, In, Ti, Ge, P, As, Sb, Bi, S, and Se.

Silicon Oxide Compound

The porous silicon-based-carbon composite according to an embodiment of the present invention may further comprise a silicon oxide compound.

The silicon oxide compound may be a silicon-based oxide represented by the following Formula 2.

SiOₓ(0.5≤x≤2) [Formula 2]

In addition, the silicon oxide compound reacts with lithium to form compounds such as Li₄SiO₄ and Li₂O, which are strongly alkaline. These compounds as a strong alkali catalyst would cause a problem of forming a resistance component by decomposing the electrolyte. In addition, since the silicon oxide compound forms an SEI layer on the surface of a negative electrode during charging and discharging, the resistance of the electrode increases, which may be unsuitable for high power. For this reason, it is not desirable for the silicon oxide compound to fall outside the above range.

The silicon oxide compound may be preferably SiOₓ (0.5≤x≤1.5), more preferably SiOₓ (0.8<x≤1.2), and even more preferably SiOₓ (0.9<x≤1.1). In the formula SiOₓ, if the value of x is less than 0.5, expansion and contraction may be increased and lifespan characteristics may be deteriorated during the charging and discharging of the secondary battery. In addition, if x exceeds 2, there may be a problem in that the initial efficiency of the secondary battery is decreased as the amount of inactive oxides increases.

The silicon oxide compound may be employed in an amount of 0.1% by mole to 10% by mole, preferably, 0.1% by mole to 5% by mole, based on the total weight of the porous silicon-based-carbon composite.

If the content of the silicon oxide compound is less than 0.1% by weight, the volume of the secondary battery may expand, and the lifespan characteristics thereof may be deteriorated. On the other hand, if the content of the silicon oxide compound exceeds 10% by weight, the initial irreversible reaction of the secondary battery may be increased, thereby deteriorating the initial efficiency.

Pores

In the porous silicon-based-carbon composite according to an embodiment of the present invention, the pores formed therein can minimize or alleviate the volume expansion of the negative electrode active material during charging and discharging, thereby enhancing the lifespan characteristics of the lithium secondary battery. In addition, since the pores can be impregnated with a non-electrolyte, lithium ions can penetrate into the inside of the composite, which expedites the efficient diffusion of lithium ions, so that high charging and discharging rates can be achieved.

In addition, in the porous silicon-based-carbon composite, the volume expansion that takes place during the charging and discharging of the secondary battery is concentrated on the pores rather than the outer part of the negative electrode active material, thereby effectively controlling the volume expansion and enhancing the lifespan characteristics of the lithium secondary battery. In addition, the electrolyte can easily penetrate into the porous structure to enhance the output characteristics, so that the performance of the lithium secondary battery can be further enhanced.

In the present specification, pores may be used interchangeably with voids. In addition, the pores may comprise open pores, closed pores, or both. The closed pores refer to independent pores that are not connected to other pores because all of the walls of the pores are formed in a closed structure. In addition, the open pores are formed in an open structure in which at least a part of the walls of the pores are open, so that they may be, or may not be, connected to other pores. In addition, they may refer to pores exposed to the outside as they are disposed on the surface of the porous silicon composite.

Open pores can be identified as pore volume by gas adsorption behavior. Closed pores can be identified by cutting the particles and observing them with an electron microscope.

The porosity of the porous silicon-based-carbon composite may be 1% by volume to 20% by volume, preferably, 1% by volume to 10% by volume, based on the volume of the porous silicon-based-carbon composite. The porosity may be a porosity of the closed pores in the porous silicon-based-carbon composite.

Here, porosity refers to “(pore volume per unit mass)/{(specific volume+pore volume per unit mass)}.” It may be measured by a mercury porosimetry method or a Brunauer- Emmett-Teller (BET) measurement method.

In the present specification, the specific volume is calculated as 1/(particle density) of a sample. The pore volume per unit mass is measured by the BET method to calculate the porosity (%) from the above equation.

If the porosity of the porous silicon-based-carbon composite satisfies the above range, it is possible to obtain a buffering effect of volume expansion while maintaining sufficient mechanical strength when it is applied to a negative electrode active material of a secondary battery. Thus, it is possible to minimize the problem of volume expansion due to the use of silicon particles, to achieve high capacity, and to enhance the lifespan characteristics. If the porosity of the porous silicon-based-carbon composite is less than 1% by volume, it may be difficult to control the volume expansion of the negative electrode active material during charging and discharging. If it exceeds 20% by volume, the mechanical strength is reduced due to a large number of pores present in the negative electrode active material, and there is a concern that the negative electrode active material may be collapsed in the process of manufacturing a secondary battery, for example, during the mixing of the negative electrode active material slurry and the rolling step after coating.

According to an embodiment of the present invention, a porous silicon-based composite in which a plurality of pores are formed inside the porous silicon-based-carbon composite may be obtained by etching. In particular, it is preferable that closed pores are formed inside the porous silicon-based-carbon composite.

Meanwhile, the state of formation of pores may be significantly different before and after forming a carbon layer (carbon film) on the porous silicon-based-carbon composite. The pores before forming a carbon layer are formed after removing silicon dioxide. In such a case, it is considered that the pores may be present in an open pore state. After forming a carbon layer, it is assumed that a significant number of the open pores are in a closed pore state since they can be covered by carbon. Although the cross-section of the composite particles may be observed with FE-SEM or TEM for the state of formation of such pores, it often shows a complex shape or form.

The porous silicon-based-carbon composite may comprise a plurality of pores, and the diameters of the pores may be the same as, or different from, each other.

Carbon

The porous silicon-based-carbon composite according to an embodiment of the present invention comprises carbon.

According to an embodiment of the present invention, as the porous silicon-based-carbon composite comprises carbon, it is possible to secure adequate electrical conductivity of the porous silicon-based-carbon composite and to adjust the specific surface area appropriately. Thus, when it is used as a negative electrode active material of a secondary battery, the lifespan characteristics and capacity of the secondary battery can be enhanced.

In general, the electrical conductivity of a negative electrode active material is an important factor for facilitating electron transfer during an electrochemical reaction. If the composite as a negative electrode active material does not comprise carbon, for example, when a high-capacity negative electrode active material is prepared using silicon particles and fluorine-containing magnesium compound, the electrical conductivity may not reach an appropriate level.

Thus, the present inventors have formed a carbon layer on the surface of a porous silicon composite comprising silicon particles and a magnesium compound, whereby it is possible to improve the charge and discharge capacity, initial charge efficiency, and capacity retention rate, to enhance the mechanical properties, to impart excellent electrical conductivity even after charging and discharging have been carried out and the electrode has been expanded, to suppress the side reaction of the electrolyte, and to further enhance the performance of the lithium secondary battery.

Specifically, the porous silicon-based-carbon composite comprises a porous silicon composite and a carbon layer on its surface, wherein the silicon particles and the magnesium compound may be present in the porous silicon composite, and the carbon may be present in the carbon layer. For example, the silicon particles and the magnesium compound may be present in the porous silicon composite, and carbon may be present on a part or all of the surfaces of at least one selected from the group consisting of the silicon particles and the magnesium compound to form a carbon layer. Here, the silicon particles and the magnesium compound may have a uniformly dispersed structure. As the porous silicon-based-carbon composite comprises a carbon layer, it is possible to solve the difficulty of electrical contact between particles due to the presence of pores and to provide excellent electrical conductivity even after the electrode has been expanded during charging and discharging, so that the performance of the secondary battery can be further enhanced.

Specifically, carbon may be present on the surface of the silicon particles, the silicon aggregates, or both. In addition, if the silicon-based-carbon composite further comprises a silicon oxide (SiOₓ, 0.1<x≤2) formed on the surface of the silicon aggregates, the carbon may be present on the surface of the silicon oxide (SiOₓ, 0.1<x≤2). In addition, carbon may be present on the surface of the magnesium compound. That is, carbon may be present on the surface of the fluorine-containing magnesium compound, magnesium silicate, and both.

In addition, according to an embodiment of the present invention, the thickness of the carbon layer or the amount of carbon may be controlled, so that it is possible to achieve appropriate electrical conductivity, as well as to prevent a deterioration of the lifespan characteristics, to thereby achieve a high-capacity negative electrode active material.

The porous silicon-based-carbon composite on which a carbon layer is formed may have an average particle diameter (D₅₀) of 2 μm to 15 μm. In addition, the average particle diameter is a value measured as a volume average value D₅₀, i.e., a particle diameter or median diameter when the cumulative volume is 50% in particle size distribution measurement according to a laser beam diffraction method. Specifically, the average particle diameter (D₅₀) of the porous silicon-based-carbon composite may be preferably 3 μm to 10 μm, more preferably 3 μm to 8 μm.

If the average particle diameter of the porous silicon-based-carbon composite is less than 2 μm, there is a concern that the dispersibility may be deteriorated due to the aggregation of particles of the composite during the preparation of a negative electrode slurry (i.e., a negative electrode active material composition) using the same. In addition, if the average particle diameter of the porous silicon-based-carbon composite exceeds 15 μm, the expansion of the composite particles due to the charging of lithium ions becomes severe, and the binding capability between the particles of the composite and the binding capability between the particles and the current collector are deteriorated as charging and discharging are repeated, so that the lifespan characteristics may be significantly reduced. In addition, there is a concern that the activity may be deteriorated due to a decrease in the specific surface area.

According to an embodiment, the content of carbon (C) may be 3% by weight to 60% by weight, preferably, 10% by weight to 50% by weight, more preferably, 20% by weight to 50% by weight, based on the total weight of the porous silicon-based-carbon composite. If the content of carbon (C) is less than 3% by weight, a sufficient effect of enhanced conductivity cannot be expected, and there is a concern that the electrode lifespan of the lithium secondary battery may be deteriorated. In addition, if it exceeds 60% by weight, the discharge capacity of the secondary battery may decrease and the bulk density may decrease, so that the charge and discharge capacity per unit volume may be deteriorated.

The carbon layer may have an average thickness of 1 nm to 300 nm, preferably, 5 nm to 200 nm, more preferably, 5 nm to 150 nm, more specifically, 10 nm to 100 nm. If the thickness of the carbon layer is 1 nm or more, an enhancement in conductivity may be achieved. If it is 300 nm or less, a decrease in the capacity of the secondary battery may be suppressed.

The average thickness of the carbon layer may be measured, for example, by the following procedure.

First, the negative electrode active material is observed at an arbitrary magnification by a transmission electron microscope (TEM). The magnification is preferably, for example, a degree that can be confirmed with the naked eye. Subsequently, the thickness of the carbon layer is measured at arbitrary 15 points. In such an event, it is preferable to select the measurement positions at random widely as much as possible, without concentrating on a specific region. Finally, the average value of the thicknesses of the carbon layer at the 15 points is calculated.

The carbon layer may comprise at least one selected from graphene, reduced graphene oxide, a carbon nanotube, a carbon nanofiber, and graphite. Specifically, it may comprise graphene.

In addition, the porous silicon-based-carbon composite is a composite in which a plurality of silicon particles are uniformly distributed in a composite whose structure is in the form of a single mass, for example, a polyhedral, spherical, or similar shape. It may be in a single structure in which carbon, more specifically, a carbon layer comprising carbon surrounds a part or all of the surfaces of one or more silicon particles or the surfaces of secondary silicon particles (clumps), that is, silicon aggregates, formed by the aggregation of two or more silicon particles.

The porous silicon-based-carbon composite may have a specific surface area (Brunauer-Emmett-Teller method; BET) of 2 m²/g to 60 m²/g, preferably, 3 m²/g to 50 m²/g, more preferably, 3 m²/g to 40 m²/g. If the specific surface area of the porous silicon-based-carbon composite is less than 2 m²/g, the rate characteristics of the secondary battery may be deteriorated. If it exceeds 60 m²/g, it may be difficult to prepare a negative electrode slurry suitable for the application to a negative electrode current collector, the contact area with an electrolyte is increased, and the decomposition reaction of the electrolyte may be accelerated or a side reaction of the secondary battery may be caused.

The porous silicon-based-carbon composite may have a specific gravity of 1.8 g/cm³ to 2.5 g/cm³, preferably, 2.0 g/cm³ to 2.5 g/cm³, more preferably, 2.0 g/cm³ to 2.4 g/cm³. The specific gravity of a porous silicon-based-carbon composite may vary depending on the coating amount of a carbon layer and the removed amount of silicon dioxide. While the amount of carbon is fixed, the greater the specific gravity within the above range, the fewer pores in the composite. Therefore, when it is used as a negative electrode active material, the conductivity is enhanced, and the strength of the matrix is fortified, thereby enhancing the initial efficiency and cycle lifespan characteristics. Here, specific gravity may refer to particle density, density, or true density. According to an embodiment of the present invention, for the measurement of specific gravity, for example, for the measurement of specific gravity by a dry density meter, Acupick II 1340 manufactured by Shimadzu Corporation may be used as a dry density meter. The purge gas to be used may be helium gas, and the measurement may be carried out after 200 times of purge in a sample holder set at a temperature of 23° C.

If the specific gravity of the porous silicon-based-carbon composite is 1.8 g/cm³ or more, the dissociation between the negative electrode active material powder due to volume expansion of the negative electrode active material powder during charging may be prevented, and the cycle deterioration may be suppressed. If the specific gravity is 2.5 g/cm³ or less, the impregnability of an electrolyte is enhanced, which increases the utilization rate of the negative electrode active material, so that the initial charge and discharge capacity can be enhanced.

<Process for Preparing the Porous silicon-based-carbon composite>

The process for preparing the porous silicon-based-carbon composite according to an embodiment of the present invention comprises a first step of obtaining a silicon composite oxide powder using a silicon-based raw material and a magnesium-based raw material; a second step of etching the silicon composite oxide powder using an etching solution comprising a fluorine (F) atom-containing compound; a third step of filtering and drying the composite obtained by the etching to obtain a porous silicon composite; and a fourth step of forming a carbon layer on the surface of the porous silicon composite by using a chemical thermal decomposition deposition method.

The preparation process according to an embodiment has an advantage in that mass production is possible through a continuous process with minimized steps.

According to an embodiment of the present invention, the porous silicon-based-carbon composite comprises a porous silicon composite and a carbon layer on its surface, the silicon particles and magnesium compound are present in the porous silicon composite, and the carbon is present on a part or all of the surfaces of at least one selected from the group consisting of the silicon particles and the magnesium compound to form a carbon layer.

Specifically, in the process for preparing the porous silicon-based-carbon composite, the first step may comprise obtaining a silicon composite oxide powder using a silicon-based raw material and a magnesium-based raw material.

The silicon-based raw material may comprise at least one selected from the group consisting of a silicon powder, a silicon oxide powder, and a silicon dioxide powder.

The magnesium-based raw material may comprise metallic magnesium.

The first step may be carried out by, for example, using the method described in Korean Laid-open Patent Publication No. 2018-0106485.

Meanwhile, a thin film composed of silicon oxide (SiOₓ, 0.1<x≤2) is easily formed on the surfaces of the silicon particles before etching in the second step.

The molar ratio of oxygen atoms to silicon (Si) atoms (O/Si) in the silicon composite oxide is preferably 0.85 to 1.3. More preferably, the molar ratio of oxygen atoms to silicon (Si) atoms (O/Si) in the silicon composite oxide may be 0.85 to 1.2. If the molar ratio of oxygen atoms to silicon (Si) atoms (O/Si) in the silicon composite oxide is less than 0.85, there may be difficulties in the preparation process. In addition, if the molar ratio of oxygen atoms to silicon (Si) atoms (O/Si) in the silicon composite oxide exceeds 1.3, the ratio of inactive silicon dioxide or silicon oxide would be too large during thermal treatment in the preparation process, which may cause deterioration in the charge and discharge capacity.

The silicon composite oxide before etching may have a specific surface area (Brunauer-Emmett-Teller method; BET) of 3 m²/g to 50 m²/g, preferably, 3 m²/g to 40 m²/g, more preferably, 3 m²/g to 30 m²/g, even more preferably, 3 m²/g to 20 m²/g.

The silicon composite oxide may have a specific gravity (particle density) of 1.8 g/cm³ to 2.8 g/cm³, preferably, 2.0 g/cm³ to 2.8 g/cm³, more preferably, 2.2 g/cm³ to 2.7 g/cm³.

According to an embodiment of the present invention, the process may further comprise forming a carbon layer on the surface of the silicon composite oxide powder by using a chemical thermal decomposition deposition method.

Specifically, once a carbon layer has been formed on the surface of the silicon composite oxide powder using a silicon-based raw material and a magnesium-based raw material, the etching process of the second step may be carried out. In such a case, there may be an advantage in that uniform etching is possible, and a high yield may be obtained.

The step of forming a carbon layer may be carried out by a process similar, or identical, to the process of forming a carbon layer in the fourth step to be described below.

When a carbon layer is formed on the surface of the silicon composite oxide powder, the silicon composite oxide on which a carbon layer has been formed may have a specific surface area (Brunauer-Emmett-Teller method; BET) of 2 m²/g to 60 m²/g, preferably, 3 m²/g to 50 m²/g, more preferably, 3 m²/g to 40 m²/g. If the specific surface area of the silicon composite oxide on which a carbon layer has been formed is less than 2 m²/g, the average particle diameter of the particles is too large. Thus, when it is applied onto a current collector as a negative electrode active material of a secondary battery, an uneven electrode may be formed, which impairs the lifespan of the secondary battery. If it exceeds 60 m²/g, it is difficult to control the heat generated by the etching reaction in the etching process of the second step, and the yield of the porous silicon composite after etching may be reduced.

In the process for preparing the porous silicon-based-carbon composite, the second step may comprise etching the silicon composite oxide powder using an etching solution comprising a fluorine (F) atom-containing compound.

The etching step may comprise dry etching and wet etching.

If dry etching is used, selective etching may be possible.

Silicon dioxide of the silicon composite oxide powder is dissolved and eluted by the etching step to thereby form pores.

A part of the magnesium silicate is converted to fluorine-containing magnesium compound by the etching step, so that a porous silicon composite comprising silicon particles, magnesium silicate, and fluorine-containing magnesium compound may be prepared.

The silicon composite oxide powder is etched using an etching solution comprising a fluorine (F) atom-containing compound in the etching step to thereby form pores.

The silicon composite oxide powder is etched using a fluorine (F) atom-containing compound (e.g., HF) to convert a part of magnesium silicate to fluorine-containing magnesium compound, and pores are formed at the same time in the portion from which silicon dioxide has been eluted and removed. As a result, a porous silicon composite comprising silicon particles, magnesium silicate, and fluorine-containing magnesium compound may be prepared.

For example, in the etching step in which HF is used, when dry etching is carried out, it may be represented by the following Reaction Schemes G1 and G2, and when wet etching is carried out, it may be represented by the following Reaction Schemes L1a to L2:

MgSi₃+6HF (gas)→SiF₄ (g)+MgF₂+3H₂O (G1)

Mg₂SiO₄+8HF (gas)→SiF₄ (g)+2MgF₂+4H₂O (G2)

MgSiO₃+6HF (aq. solution)→MgSiF₆+3H₂O (L1a)

MgSiF₆+2HF (aq. solution)→MgF₂+H₂SiF₆ (L1b)

MgSiO₃+2HF→SiO₂+MgF₂+H₂O (L1c)

SiO₂+6HF (l)→H₂SiF₆+2H₂O (L1d)

MgSiO₃+8HF (aq. solution)→MgF₂+H₂SiF₆+3H₂O (L1)

Mg₂SiO₄+8HF (aq. solution)→MgSiF₆+MgF₂+4H₂O (L2a)

MgSiF₆+2HF (aq. solution)→MgF₂+H₂SiF₆ (L2b)

Mg₂SiO₄+4HF (aq. solution)→SiO₂+2MgF₂+2H₂O (L2c)

SiO₂+6HF (aq. solution)→H₂SiF₆+2H₂O (L2d)

Mg₂SiO₄+10HF (aq. solution)→2MgF₂+H₂SiF₆+4H₂O (L2)

In addition, pores may be considered to be formed by the following Reaction Schemes (A) and (B).

SiO₂+4HF (gas)→SiF₄+2H₂O (A)

SiO₂+6HF (aq. solution)→H₂SiF₆+2H₂O (B)

Pores (voids) may be formed where silicon dioxide is dissolved and removed in the form of SiF₄ and H₂SiF₆ by the reaction mechanism as in the above reaction schemes.

In particular, pores or voids can be formed at the locations where silicon dioxide is removed. As a result, the specific surface area of the porous silicon composite may be increased as compared with the specific surface area of the silicon composite oxide before etching.

In addition, according to an embodiment of the present invention, in the porous silicon composite obtained by the etching before the carbon coating, pores may be present on its surface, inside, or both. The surface of the porous silicon composite may refer to the outermost portion of the porous silicon composite. The inside of the porous silicon composite may refer to a portion other than the outermost portion, that is, an inner portion of the outermost portion.

In addition, silicon dioxide contained in the porous silicon composite may be removed depending on the degree of etching, and pores may be formed therein.

The degree of formation of pores may vary with the degree of etching. For example, pores may be hardly formed, or pores may be partially formed, specifically, pores may be formed only in the outer portion.

In addition, the specific surface area and specific gravity in the porous silicon composite in which pores are formed may significantly vary before and after the coating of carbon.

According to an embodiment of the present invention, the composite after etching may comprise a magnesium compound. for example, crystals of both magnesium silicate and fluorine-containing magnesium compound may be contained.

It is possible to obtain a porous silicon composite powder having a plurality of pores formed on the surface of the composite particles, or on the surface and inside thereof, through the etching.

Here, etching refers to a process in which the silicon composite oxide powder is treated with an etching solution containing a fluorine (F) atom-containing compound.

A commonly used etching solution may be used without limitation within a range that does not impair the effects of the present invention as the etching solution containing a fluorine (F) atom-containing compound.

In the second step, the etching solution may further comprise one or more acids selected from the group consisting of organic acids, sulfuric acid, hydrochloric acid, phosphoric acid, nitric acid, and chromic acid.

Specifically, as a method of treating with the etching solution, the silicon composite oxide powder may be stirred using an etching solution containing a fluorine (F) atom-containing compound in a solution containing the acid. The stirring temperature (treatment temperature) is not particularly limited. For example, it may be 20° C. to 90° C.

Specifically, a fluorine (F) atom-containing compound may be used as the etching solution and comprise, for example, at least one selected from the group consisting of HF, NH₄F, and HF₂. As the fluorine (F) atom-containing compound is used, the porous silicon-based-carbon composite may comprise fluorine-containing magnesium compound, and the etching step may be carried out more quickly.

Meanwhile, in the second step, the silicon composite oxide powder may be dispersed in a dispersion medium, and etching may be then carried out. The dispersion medium may comprise at least one selected from the group consisting of water, alcohol-based compounds, ketone-based compounds, ether-based compounds, hydrocarbon-based compounds, and fatty acids.

In the silicon composite oxide powder, a part of silicon oxide may remain in addition to silicon dioxide, and the portion from which silicon oxide such as silicon dioxide or silicon oxide is removed by the etching may form voids or pores inside the particles.

The composite obtained upon the etching is porous and may comprise silicon particles and a magnesium compound. In addition, the composite obtained upon the etching may comprise fluorine-containing magnesium compound. In addition, the composite obtained upon the etching may comprise a mixture of magnesium silicate and fluorine-containing magnesium compound.

It is possible to obtain a porous composite having a plurality of pores formed on the surface, inside, or both of the composite particles through the etching. When the composite is applied to a negative electrode active material, the electrochemical properties, particularly, the lifespan characteristics of the lithium secondary battery can be remarkably improved.

In addition, as the selective etching removes a large amount of silicon dioxide, the silicon particles may comprise silicon (Si) in a very high fraction as compared with oxygen (O) on their surfaces. That is, the molar ratio of oxygen (O) atoms to silicon (Si) atoms (O/Si) present in the porous silicon composite may be significantly reduced. In such a case, a secondary battery having a high capacity and excellent cycle characteristics as well as an improved first charge and discharge efficiency can be obtained.

In addition, pores or voids can be formed at the locations where silicon dioxide is removed. As a result, the specific surface area of the porous silicon composite may be increased as compared with the specific surface area of the silicon composite oxide before etching.

According to an embodiment of the present invention, the porous silicon composite upon etching and before carbon coating may mainly comprise silicon particles, a magnesium compound, silicon oxide, and silicon dioxide. According to an embodiment of the present invention, it is characterized in that the contents of silicon oxide, silicon dioxide, or both are low upon etching.

In addition, the particle size distribution and average particle size of the porous silicon composite powder obtained by etching the silicon composite oxide may be substantially the same as the particle size distribution and average particle size of the silicon composite oxide powder before etching. The change in the average size of the particles may be within 10% and, more preferably, may be readily controlled within 5%.

In general, in the preparation of the porous silicon-based-carbon composite, a thin film of silicon oxide tends to be formed on the surfaces of the silicon particles before and after etching. Since the surfaces of silicon particles can be easily oxidized, it is necessary to reduce the amount of oxygen in the silicon particles as much as possible. Meanwhile, the oxide layer formed on the surface of the silicon particles reduces the reactivity between the negative electrode active material and the electrolyte depending on the thickness of the oxide layer, thereby minimizing the formation of a side reaction product layer that may be formed on the surface of the negative electrode active material.

The silicon particles tend to form a natural film having a high oxygen fraction, that is, a silicon oxide film formed by natural oxidation of the surfaces of the silicon particles by oxygen or water in the air during filtration, drying, pulverization, and classification. The molar ratio of oxygen (O) atoms to silicon (Si) atoms (O/Si) present in the porous silicon composite may be 0.40 to 0.90, preferably, 0.40 to 0.80, more preferably, 0.40 to 0.70, even more preferably, 0.40 to 0.60.

In the porous silicon composite (precursor before carbon coating) obtain upon etching, the content of silicon (Si) may be 10% by weight to 90% by weight, preferably, 20% by weight to 80% by weight, more preferably, 30% by weight to 70% by weight, based on the total weight of the porous silicon composite.

If the content of silicon (Si) is less than 10% by weight, the amount of an active material for occlusion and release of lithium is small, which may reduce the charge and discharge capacity of the lithium secondary battery. On the other hand, if it exceeds 90% by weight, the charging and discharge capacity of the lithium secondary battery may be increased, whereas the expansion and contraction of the electrode during charging and discharging may be excessively increased, and the negative electrode active material powder may be further atomized, which may deteriorate the cycle characteristics.

The content of magnesium (Mg) in the porous silicon composite may be 0.2% by weight to 15% by weight, preferably, 1.5% by weight to 10% by weight, more preferably, 2% by weight to 8% by weight, based on the total weight of the porous silicon composite.

If the content of magnesium (Mg) in the porous silicon composite is less than 0.2% by weight, there may be a problem in that the cycle characteristics of the secondary battery are deteriorated. If it exceeds 15% by weight, there may be a problem in that the charge capacity of the secondary battery is reduced.

According to an embodiment of the present invention, physical properties such as element content and specific surface area may vary before and after the etching step. That is, physical properties such as element content and specific surface area in the silicon composite oxide before the etching step and the porous silicon composite after the etching step may vary.

For example, the content of magnesium (Mg) in the porous silicon composite may decrease or increase as compared with that in the silicon composite oxide.

In addition, a reduction rate of oxygen (O) in the porous silicon composite relative to the silicon composite oxide may be 5% to 50%, preferably, 8% to 48%, more preferably, 10% to 47%.

In addition, the specific surface area (Brunauer-Emmett-Teller Method; BET) of the porous silicon composite may be increased by 0.1 to 200 times, specifically, 0.5 to 80 times, as compared with the specific surface area of the silicon composite oxide before etching.

In addition, the porous silicon composite may be formed from a silicon composite oxide comprising silicon particles and magnesium silicate. It is a composite in which a plurality of silicon particles are uniformly distributed in a composite whose structure is in the form of a single mass, for example, a polyhedral, spherical, or similar shape. It may be secondary silicon particles (clumps) formed by aggregation of two or more silicon particles to be connected with each other, that is, in which a porous silicon structure comprising silicon aggregates is formed.

In addition, the porous silicon composite according to an embodiment of the present invention may comprise pores. Specifically, pores may be contained on the surface, inside, or both of the porous silicon composite.

In the process for preparing the porous silicon-based-carbon composite, the third step may comprise filtering and drying the composite obtained by the etching to obtain a porous silicon composite.

The filtration and drying step may be carried out by a commonly used method.

In the process for preparing the porous silicon-based-carbon composite, the fourth step may comprise forming a carbon layer on the surface of the porous silicon composite by using a chemical thermal decomposition deposition method.

The electrical contact between the particles of the porous silicon-based-carbon composite may be enhanced by the step of forming a carbon layer. In addition, as the charge and discharge are carried out, excellent electrical conductivity may be imparted even after the electrode is expanded, so that the performance of the secondary battery can be further enhanced. Specifically, the carbon layer may increase the conductivity of the negative electrode active material to enhance the output characteristics and cycle characteristics of the battery and may increase the stress relaxation effect when the volume of the active material is changed.

The carbon layer may comprise at least one selected from the group consisting of graphene, reduced graphene oxide, a carbon nanotube, a carbon nanofiber, and graphite.

The step of forming a carbon layer may be carried out by injecting at least one carbon source gas selected from a compound represented by the following Formulae 1 to 3 and carrying out a reaction of the porous silicon composite obtained in the third step in a gaseous state at 400° C. to 1,200° C.

C_{N}H_{(2N+2-A)}[OH]_{A} [Formula 1]

in Formula 1, N is an integer of 1 to 20, and A is 0 or 1,

C_{N}H_{(2N-B)} [Formula 2]

in Formula 2, N is an integer of 2 to 6, and B is 0 to 2,

CₓH_{y}O_{z} [Formula 3]

in Formula 3, x is an integer of 1 to 20, y is an integer of 0 to 25, and z is an integer of 0 to 5.

The compound represented by Formulae 1 and 2 may be at least one selected from methane, ethylene, propylene, methanol, ethanol, and propanol.

Meanwhile, the compound represented by Formula 3 may be an oxygen-containing gas and, for example, at least one selected from carbon dioxide and carbon monoxide. Alternatively, the compound represented by Formula 3 may comprise acetylene.

The carbon source gas may further comprise at least one inert gas selected from hydrogen, nitrogen, helium, and argon.

The reaction may be carried out at 400° C. to 1,200° C., specifically, 500° C. to 1,100° C., more specifically, 600° C. to 1,000° C.

The reaction time (or thermal treatment time) may be appropriately adjusted depending on the thermal treatment temperature, the pressure during the thermal treatment, the composition of the gas mixture, and the desired amount of carbon coating. For example, the reaction time may be 10 minutes to 100 hours, specifically, 30 minutes to 90 hours, more specifically, 50 minutes to 40 hours, but it is not limited thereto. Without being bound by a particular theory, as the reaction time is longer, the thickness of the carbon layer formed increases, which may enhance the electrical properties of the composite.

In the process for preparing the porous silicon-based-carbon composite according to an embodiment of the present invention, it is possible to form a thin and uniform carbon layer comprising at least one selected from graphene, reduced graphene oxide, a carbon nanotube, a carbon nanofiber, and graphite as a main component on the surface of the porous silicon composite even at a relatively low temperature through a gas-phase reaction of the carbon source gas. In addition, the detachment reaction in the carbon layer thus formed does not substantially take place.

In addition, since a carbon layer is uniformly formed over the entire surface of the porous silicon composite through the gas-phase reaction, a carbon film (carbon layer) having high crystallinity can be formed. Thus, when the porous silicon-based-carbon composite is used as a negative electrode active material, the electrical conductivity of the negative electrode active material can be enhanced without changing the structure.

According to an embodiment of the present invention, when a reactive gas containing the carbon source gas is supplied to the surface of the porous silicon composite, one or more graphene-containing materials selected from graphene, reduced graphene oxide, and graphene oxide, a carbon nanotube, or a carbon nanofiber is grown on the surface of the silicon particles. As the reaction time elapses, the graphene-containing material is gradually distributed and formed to obtain a porous silicon-based-carbon composite.

The specific surface area of the porous silicon-based-carbon composite may decrease according to the amount of carbon coating.

The structure of the graphene-containing material may be a layer, a nanosheet type, or a structure in which several flakes are mixed.

If a carbon layer comprising a graphene-containing material is uniformly formed over the entire surface of the porous silicon composite, it is possible to suppress volume expansion as a graphene-containing material that has enhanced conductivity and is flexible for volume expansion is directly grown on the surface of silicon particles or fluorine-containing magnesium compound. In addition, the coating of a carbon layer may reduce the chance that silicon directly meets the electrolyte, thereby reducing the formation of a solid electrolyte interphase (SEI) layer.

In addition, the porous silicon-based-carbon composite may have an average particle diameter (D₅₀) in the volume-based distribution measured by laser diffraction of 2 μm to 15 μm, preferably, 3 μm to 10 μm, more preferably, 3 μm to 8 μm, or even more preferably, 3 μm to 6 μm. If D₅₀ is less than 2 μm, the bulk density is too small, and the charge and discharge capacity per unit volume may be deteriorated. On the other hand, if D₅₀ exceeds 15 μm, it is difficult to prepare an electrode layer, so that it may be peeled off from the electrical power collector. The average particle diameter (D₅₀) is a value measured as a volume average value D₅₀, i.e., a particle size or median diameter when the cumulative volume is 50% in particle size distribution measurement according to a laser beam diffraction method.

In addition, according to an embodiment of the present invention, the process may further comprise pulverizing or crushing and classifying the porous silicon-based-carbon composite. The classification may be carried out to adjust the particle size distribution of the porous silicon-based-carbon composite, for which dry classification, wet classification, or classification using a sieve may be used. In the dry classification, the steps of dispersion, separation, collection (separation of solids and gases), and discharge are carried out sequentially or simultaneously using an air stream, in which pretreatment (adjustment of moisture, dispersibility, humidity, and the like) is carried out prior to the classification so as not to decrease the classification efficiency caused by interference between particles, particle shape, airflow disturbance, velocity distribution, and influence of static electricity, and the like, to thereby adjust the moisture or oxygen concentration in the air stream used. In addition, a desired particle size distribution may be obtained by carrying out crushing or pulverization and classification at one time. After the crushing or pulverization, it is effective to divide the coarse powder part and the granular part with a classifier or sieve.

A porous silicon-based-carbon composite powder having an average particle diameter of 2 μm to 15 μm, preferably, 3 μm to 10 μm, more preferably, 3 μm to 8 μm, even more preferably, 3 μm to 6 μm, may be obtained through the pulverization or crushing and classification treatment.

The porous silicon-based-carbon composite powder may have a Dmin of 0.3 μm or less and a Dmax of 8 μm to 30 μm. Within the above ranges, the specific surface area of the composite may be reduced, and the initial efficiency and cycle characteristics may be enhanced by about 10% to 20% as compared with before classification. The composite powder upon the crushing or pulverization and classification has an amorphous grain boundary and a crystal grain boundary, so that particle collapse by a charge and discharge cycle may be reduced by virtue of the stress relaxation effect of the amorphous grain boundary and the crystal grain boundary. When such silicon particles are used as a negative electrode active material of a secondary battery, the negative electrode active material of the secondary battery can withstand the stress of a change in volume expansion caused by charge and discharge and can exhibit characteristics of a secondary battery having a high capacity and a long lifespan. In addition, a lithium-containing compound such as Li₂O present in the SEI layer formed on the surface of a silicon-based negative electrode may be reduced.

According to an embodiment of the present invention, depending on before and after the etching step, that is, physical properties such as element content and specific surface area in the silicon composite oxide before the etching and the porous silicon composite or silicon-based-carbon composite after the etching may vary.

For example, the content of magnesium (Mg) in the porous silicon-based-carbon composite may decrease or increase as compared with that in the silicon composite oxide depending on the content of carbon coating.

In addition, the content of oxygen (O) in the porous silicon-based-carbon composite may be further reduced by 5% by weight to 60% by weight, more specifically, 10% by weight to 60% by weight, as compared with the content of oxygen (O) in the silicon composite oxide.

The preparation process according to an embodiment of the present invention has an advantage in that mass production is possible through a continuous process with minimized steps.

A secondary battery using the porous silicon-based-carbon composite as a negative electrode may further enhance its initial efficiency and capacity retention rate while maintaining excellent discharge capacity.

Negative Electrode Active Material

The negative electrode active material according to an embodiment of the present invention may comprise a porous silicon-carbon composite, which comprises silicon particles capable of absorbing and releasing lithium, a magnesium compound, and carbon, wherein the molar ratio of magnesium atoms to silicon atoms present in the composite (Mg/Si) is 0.02 to 0.30, and the molar ratio of oxygen atoms to silicon atoms present in the composite (O/Si) is 0.40 to 0.90.

In addition, the negative electrode active material may further comprise a carbon-based negative electrode material, specifically, a graphite-based negative electrode material.

The negative electrode active material may be used as a mixture of the porous carbon-based negative electrode material and the carbon-based negative electrode material, for example, a graphite-based negative electrode material. In such an event, the electrical resistance of the negative electrode active material can be reduced, while the expansion stress involved in charging and discharging can be relieved at the same time. The carbon-based negative electrode material may comprise, for example, at least one selected from the group consisting of natural graphite, synthetic graphite, soft carbon, hard carbon, mesocarbon, carbon fibers, carbon nanotubes, pyrolytic carbon, coke, glass carbon fibers, sintered organic high molecular compounds, and carbon black.

The content of the carbon-based negative electrode material may be 30% by weight to 90% by weight, specifically, 30% by weight to 80% by weight, more specifically, 50% by weight to 80% by weight, based on the total weight of the negative electrode active material.

In addition, the negative electrode active material may further comprise a silicon-silicon composite oxide-carbon composite.

The silicon-silicon composite oxide-carbon composite is a composite comprising a carbon component on the surface of a silicon-silicon composite oxide represented by the formula MgₓSiO_{y} (0<x<0.2, 0.8<y<1.2). The silicon-silicon composite oxide-carbon composite may comprise silicon particles capable of charging and discharging lithium ions and may comprise silicon oxide and a metal silicate salt.

Secondary Battery

According to an embodiment of the present invention, the present invention may provide a negative electrode comprising the negative electrode active material and a secondary battery comprising the same.

The secondary battery may comprise a positive electrode, a negative electrode, a separator interposed between the positive electrode and the negative electrode, and a non-aqueous liquid electrolyte in which a lithium salt is dissolved. The negative electrode may comprise a negative electrode active material comprising a porous silicon-based-carbon composite.

The negative electrode may be composed of a negative electrode mixture only or may be composed of a negative electrode current collector and a negative electrode mixture layer (negative electrode active material layer) supported thereon. Similarly, the positive electrode may be composed of a positive electrode mixture only or may be composed of a positive electrode current collector and a positive electrode mixture layer (positive electrode active material layer) supported thereon. In addition, the negative electrode mixture and the positive electrode mixture may further comprise a conductive agent and a binder.

Materials known in the art may be used as a material constituting the negative electrode current collector and a material constituting the positive electrode current collector. Materials known in the art may be used as a binder and a conductive material added to the negative electrode and the positive electrode.

If the negative electrode is composed of a current collector and an active material layer supported thereon, the negative electrode may be prepared by coating the negative electrode active material composition comprising the porous silicon-based-carbon composite on the surface of the current collector and drying it.

In addition, the secondary battery comprises a non-aqueous liquid electrolyte in which the non-aqueous liquid electrolyte may comprise a non-aqueous solvent and a lithium salt dissolved in the non-aqueous solvent. A solvent commonly used in the field may be used as a non-aqueous solvent. Specifically, an aprotic organic solvent may be used. Examples of the aprotic organic solvent include cyclic carbonates such as ethylene carbonate, propylene carbonate, and butylene carbonate, cyclic carboxylic acid esters such as furanone, chain carbonates such as diethyl carbonate, ethylmethyl carbonate, and dimethyl carbonate, chain ethers such as 1,2-methoxyethane, 1,2-ethoxyethane, and ethoxymethoxyethane, and cyclic ethers such as tetrahydrofuran and 2-methyltetrahydrofuran. They may be used alone or in combination of two or more.

The secondary battery may comprise a non-aqueous secondary battery.

The negative electrode active material and the secondary battery using the porous silicon-based-carbon composite may enhance the discharge capacity, initial discharge efficiency, and capacity retention rate thereof.

### EMBODIMENTS FOR CARRYING OUT THE INVENTION

### Example

### Example 1

Preparation of a porous silicon-based-carbon composite

(1) Step 1: A silicon composite oxide powder having the element content and physical properties shown in Table 1 below was prepared using a silicon powder, a silicon dioxide powder, and metallic magnesium by the method described in Example 1 of Korean Laid-open Patent Publication No. 2018-0106485.

(2) Step 2: 50 g of the silicon composite oxide powder was dispersed in water, which was stirred at a speed of 300 rpm, and 50 ml of an aqueous solution of 30% by weight of HF was added as an etching solution to etch the silicon composite oxide powder for 1 hour at room temperature.

(3) Step 3: The porous composite obtained by the above etching was filtered and dried at 150° C. for 2 hours. Then, in order to control the particle size of the porous composite, it was crushed using a mortar to have an average particle diameter of 5.8 μm, to thereby prepare a porous silicon composite (B1).
(4) Step 4: 10 g of the porous silicon composite was placed inside a tubular electric furnace, and argon (Ar) and methane gas flowed at a rate of 1 liter/minute, respectively. It was maintained at 900° C. for 1 hour and then cooled to room temperature, whereby the surface of the porous silicon composite was coated with carbon, to thereby prepare a porous silicon-based-carbon composite having the content of each component and physical properties shown in Table 3 below.
(5) Step 5: In order to control the particle size of the porous silicon-based-carbon composite, it was crushed and classified to have an average particle diameter of 7.46 μm by a mechanical method. A porous silicon-based-carbon composite (C1) was prepared. Here, the volume of open pores of the porous silicon-based-carbon composite powder was about 0.02 g/cc.

Fabrication of a Secondary Battery

A negative electrode and a battery (coin cell) comprising the porous silicon-based-carbon composite as a negative electrode active material were prepared.

The negative electrode active material, Super-P as a conductive material, and polyacrylic acid were mixed at a weight ratio of 80:10:10 with water to prepare a negative electrode active material composition having a solids content of 45%.

The negative electrode active material composition was applied to a copper foil having a thickness of 18 μm and dried to prepare an electrode having a thickness of 70 μm. The copper foil coated with the electrode was punched in a circular shape having a diameter of 14 mm to prepare a negative electrode plate for a coin cell.

Meanwhile, a metallic lithium foil having a thickness of 0.3 mm was used as a positive electrode plate.

A porous polyethylene sheet having a thickness of 25 μm was used as a separator. A liquid electrolyte in which LiPF₆ had been dissolved at a concentration of 1 M in a mixed solvent of ethylene carbonate (EC) and diethylene carbonate (DEC) at a volume ratio of 1:1 was used as an electrolyte. The above components were employed to fabricate a coin cell (battery) having a thickness of 3.2 mm and a diameter of 20 mm.

### Examples 2 to 7

As shown in Tables 1 to 3 below, a porous silicon-based-carbon composite was prepared in the same manner as in Example 1 and a secondary battery using the same was manufactured, except that a silicon composite oxide powder having the element content and physical properties shown in Table 1 below was used and that the type of dispersion medium, etching conditions, and the type and amount of carbon source gas were changed to adjust the content of each component and the physical properties of the composite.

### Comparative Example 1

As shown in Tables 1 to 3 below, a negative electrode active material and a secondary battery using the same were prepared in the same manner as in Example 1, except that aqua regia was used instead of the HF etching solution and etching was carried out for 12 hours at 70° C.

### Comparative Example 2

As shown in Tables 1 to 3 below, a negative electrode active material and a secondary battery using the same were prepared in the same manner as in Example 1, except that a silicon composite oxide powder having the element content and physical properties shown in Table 1 below was used, etching was not carried out, and the type of carbon source gas was changed to adjust the content of each component and the physical properties of the composite.

### Test Example

### Test Example 1 Electron Microscope Analysis

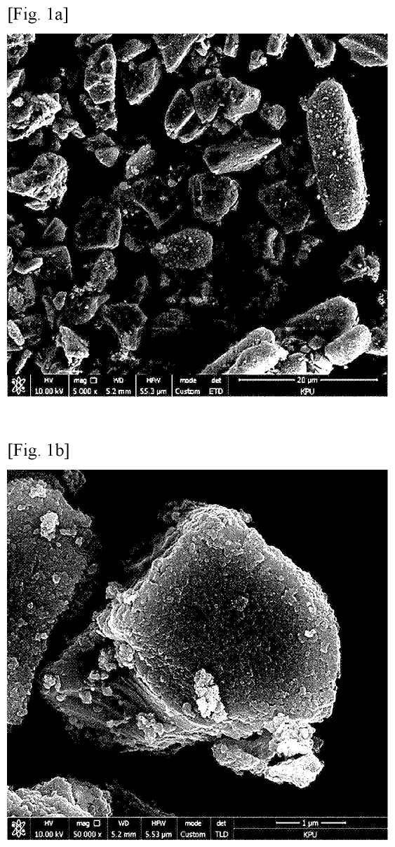

FIG. 1a is a scanning electron microscopy (FE-SEM, S-4700, Hitachi) photograph of the silicon composite oxide prepared in Example 1. In addition, FIG. 1b is a field emission scanning electron microscopy (FE-SEM) photograph of the porous silicon composite prepared in Example 1 with respect to magnification.

Referring to FIGS. 1a and 1b, pores were present on the surface of the porous silicon composite (composite B1) prepared in Example 1. In addition, the porous silicon composite (composite B1) might have a structure in which a surface and an inside of the composite were connected through open pores.

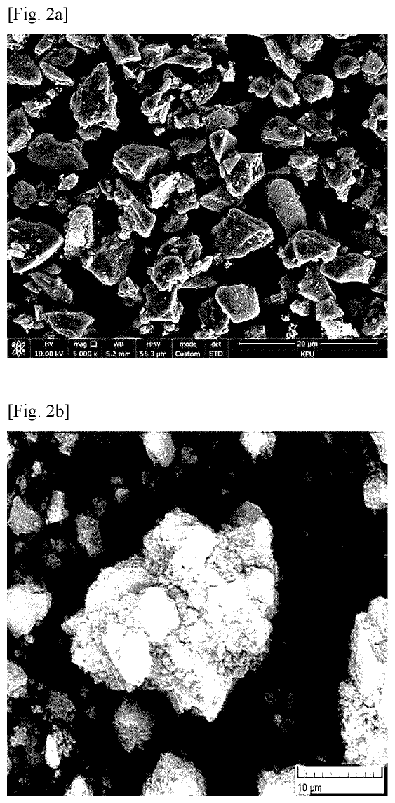

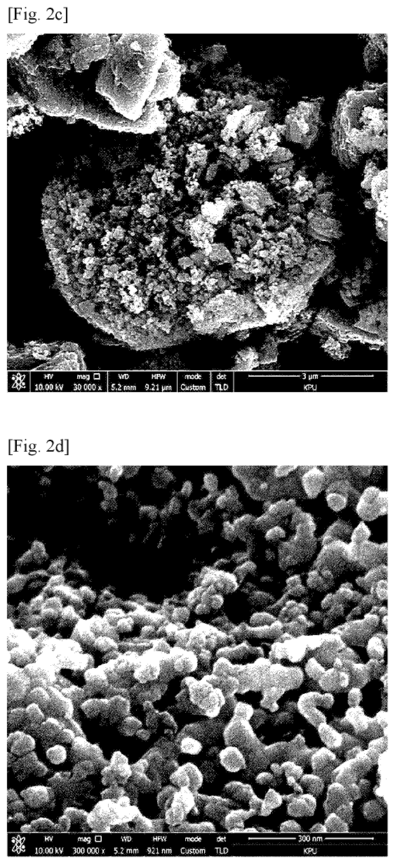

FIGS. 2a to 2d are field emission scanning electron microscopy (FE-SEM) photographs of the surface of the porous silicon-based-carbon composite prepared in Example 1. They are shown in FIGS. 2a to 2d with respect to the magnification, respectively.

As can be seen from FIGS. 2(a) to 2(d), when compared with FIG. 1a, carbon was present on the surface of the porous silicon-based-carbon composite in which the carbon surrounded fine particles contained in the porous silicon-based-carbon composite. As a result, it was confirmed that a carbon layer was formed on the surfaces of secondary silicon particles formed by the combination of silicon particles with each other, that is, silicon aggregates.

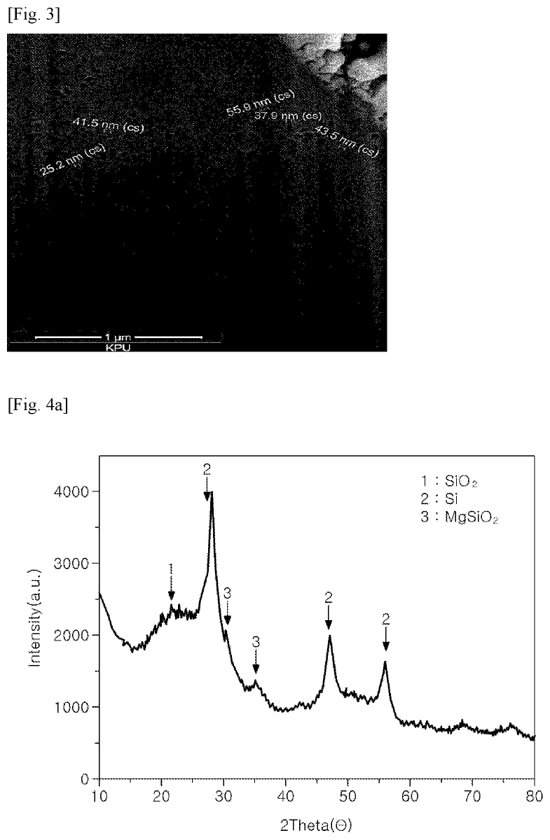

FIG. 3 is an ion beam scanning electron microscope (FIB-SEM, S-4700; Hitachi, QUANTA 3D FEG; FEI) photograph of the porous silicon-based-carbon composite prepared in Example 1 to observe the inside of the porous silicon-carbon composite.

Referring to FIG. 3, as a result of observing the inside of the porous silicon-based-carbon composite (composite C1) comprising a carbon layer on the surface of the porous silicon composite, pores were observed inside the porous silicon composite even after the carbon coating layer was formed on the surface of the porous silicon composite.

### Test Example 2 X-ray Diffraction Analysis

The crystal structures of the silicon composite oxide (composite A), the porous silicon composite (composite B), and the porous silicon-based-carbon composite (composite C) prepared in the Examples were analyzed with an X-ray diffraction analyzer (Malvern Panalytical, X'Pert3).

Specifically, the applied voltage was 40 kV, and the applied current was 40 mA. The range of 2θ was 10° to 80°, and it was measured by scanning at an interval of 0.05°.

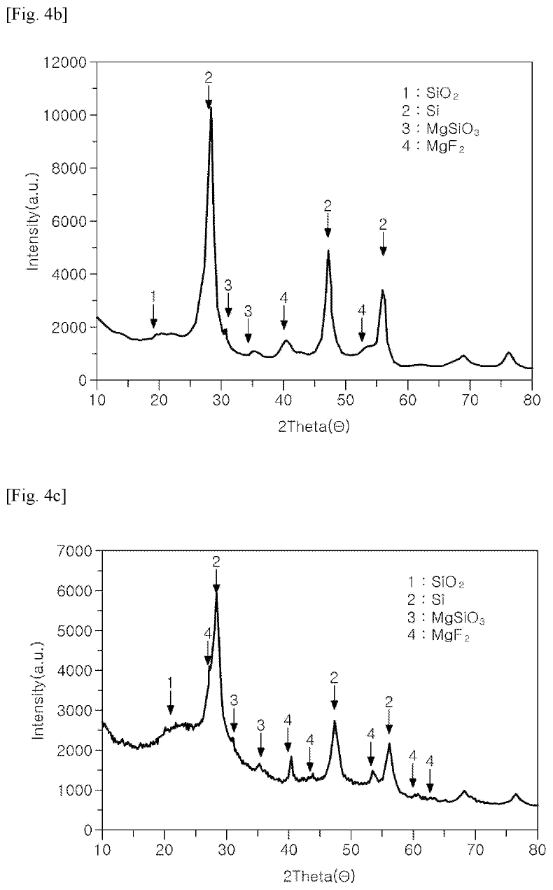

FIGS. 4a to 4c show the measurement results of an X-ray diffraction analysis of the silicon composite oxide (composite Al) (4a), the porous silicon composite (composite B1) (4b), and the porous silicon-based-carbon composite (composite C1) (4c) of Example 1.

Referring to FIG. 4a, as can be seen from the X-ray diffraction pattern, the silicon composite oxide (composite A1) of Example 1 had a peak corresponding to SiO₂ around a diffraction angle (2θ) of 22.1°; peaks corresponding to Si crystals around diffraction angles (2θ) of 28.1°, 47.0°, 55.8°, 68.6°, and 76.1°; and peaks corresponding to MgSiO₃ crystals around diffraction angles (2θ) of 30.4° and 35.0°, which confirms that the silicon composite oxide comprised amorphous SiO₂, crystalline Si, and MgSiO₃.

Referring to FIG. 4b, as can be seen from the X-ray diffraction pattern, the porous silicon composite (composite B1) of Example 1 had a peak corresponding to SiO₂ around a diffraction angle (2θ) of 22.1°; and peaks corresponding to MgF₂ crystals around diffraction angles (2θ) of 40.4° and 53.3°; and peaks corresponding to Si crystals around diffraction angles (2θ) of 28.1°, 47.0°, 55.8°, 68.6°, and 76.1°. In addition, as the peak corresponding to MgSiO₃ disappeared and a peak corresponding to MgF₂ appeared, it can be seen that MgSiO₃ was converted to MgF₂ upon etching.

Referring to FIG. 4c, as can be seen from the X-ray diffraction pattern, the porous silicon-based-carbon composite (composite C1) of Example 1 had a peak corresponding to SiO₂ around a diffraction angle (2θ) of 22.1°; and peaks corresponding to MgF2 crystals around diffraction angles (2θ) of 27.1°, 40.4°, 43.5°, 53.3°, 60.9°, and 62.5°; and peaks corresponding to Si crystals around diffraction angles (2θ) of 28.1°, 47.0°, 55.8°, 68.6°, and 76.1°. The diffraction angle (2θ) of carbon could not be confirmed since it overlapped with the Si (111) peak.

In addition, when FIGS. 4b and 4c are compared, the growth of individual crystals after carbon coating became more distinct, and a grown peak was observed.

Meanwhile, the crystal size of Si in the obtained porous silicon-based-carbon composite was determined by the Scherrer equation of the following Equation 1 based on a full width at half maximum (FWHM) of the peak corresponding to Si (220) in the X-ray diffraction analysis.

Crystal size (nm)=Kλ/B cos θ [Equation 1]

In Equation 1, K is 0.9, λ is 0.154 nm, B is a full width at half maximum (FWHM), and θ is a peak position (angle).

### Test Example 3 Analysis of the Content and Specific Gravity of the Component Elements of the Composites

The content of each component element of magnesium (Mg), silicon (Si), oxygen (O), and carbon (C) in the composites prepared in the Examples and Comparative Examples were analyzed.

The content of magnesium (Mg) was analyzed by inductively coupled plasma (ICP) emission spectroscopy. The contents of oxygen (O) and carbon (C) were measured by an elemental analyzer, respectively. The content of silicon (Si) was a value calculated based on the content of magnesium (Mg).

### Test Example 4 Measurement of an Average Particle Diameter of Composite Particles

The average particle diameter (D₅₀) of the composite particles prepared in the Examples and Comparative Examples was measured as a volume average value D₅₀, i.e., a particle size or median diameter when the cumulative volume is 50% in particle size distribution measurement according to a laser beam diffraction method.

### Test Example 5 Raman Analysis

Raman analysis was carried out using a micro-Raman analyzer (Renishaw, RM1000-In Via) at 2.41 eV (532 nm).

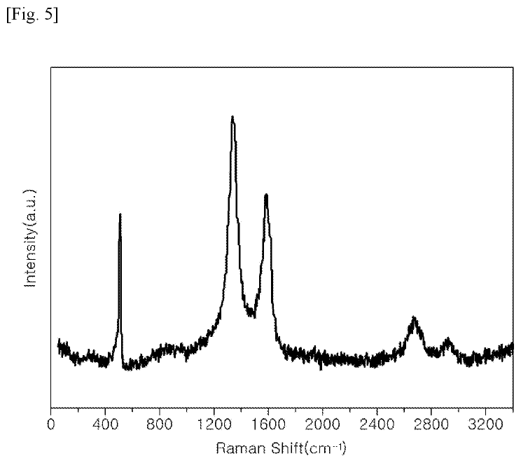

Raman analysis was performed on the porous silicon-based-carbon composites prepared in the Examples and Comparative Examples. The results are shown in FIG. 5.

As can be seen from FIG. 5, when the intensity ratio of a 2D band peak in the range of 2,600 cm⁻¹ to 2,760 cm⁻¹ is I2D, the intensity of a G band peak in the range of 1,500 cm⁻¹ to 1,660 cm⁻¹ is IG, and the intensity of a D band peak in the range of 1,300 cm⁻¹- to 1,460 cm⁻¹ is ID in the Raman spectrum, I2D was 0.1 to 0.7, IG was 0.5 to 0.8, and (I2D+IG)/ID was 0.7 to 1.5.

### Test Example 6 Measurement of Capacity, Initial Efficiency, and Capacity Retention Rate of Secondary Batteries

The coin cells (secondary batteries) prepared in the Examples and Comparative Examples were each charged at a constant current of 0.2 C until the voltage reached 0.005 V and discharged at a constant current of 0.2 C until the voltage reached 2.0 V to measure the charge capacity (mAh/g), discharge capacity (mAh/g), and initial efficiency (%). The results are shown in Table 4 below.

Initial efficiency (%)=discharge capacity/charge capacity×100 [Equation 2]

In addition, the coin cells prepared in the Examples and Comparative Examples were each charged and discharged once in the same manner as above and, from the second cycle, charged at a constant current of 0.5 C until the voltage reached 0.005 V and discharged at a constant current of 0.5 C until the voltage reached 2.0 V to measure the cycle characteristics (capacity retention rate for 50 cycles, %). The results are shown in Table 4 below.

Capacity retention rate upon 50 cycles (%)=51^{st} discharge capacity/2nd discharge capacity×100 [Equation 3]

The content of each element and physical properties of the composites prepared in the Examples and Comparative Examples are summarized in Tables 1 to 3 below. The characteristics of the secondary batteries using the same are summarized in Table 4 below.

TABLE 1

| | | Example | | | | | | | C. Ex. | |
|---|---|---|---|---|---|---|---|---|---|---|
| | | 1 | 2 | 3 | 4 | 5 | 6 | 7 | 1 | 2 |
| Silicon | Item | A1 | | | A3 | | A4 | A5 | A1 | A6 |
| composite | Mg content | 5.3 | | | 2 | | 8 | 12 | 5.3 | 16 |
| oxide | (% by weight) | | | | | | | | | |
| (Composite | D₅₀ (μm) | 5.9 | | | 5.04 | | 5.52 | 5.99 | 5.9 | 5.5 |
| A) | Particle density | 2.46 | | | 2.41 | | 2.52 | 2.64 | 2.46 | 2.65 |
| | (g/cm³) | | | | | | | | | |

| | | | | | | |
|---|---|---|---|---|---|---|
| BET (m²/g) | 10.8 | 4.84 | 5.4 | 6.7 | 10.8 | 5.8 |

TABLE 2

| | | Example | | | | | | | C. Ex. | |
|---|---|---|---|---|---|---|---|---|---|---|
| | | 1 | 2 | 3 | 4 | 5 | 6 | 7 | 1 | 2 |
| Porous | Item | B1 | B2 | B3 | B5 | B6 | B7 | B8 | | — |
| silicon | Oxygen | 12 | 26 | 42 | 15 | 42.0 | 47 | 48 | — | |
| composite | reduction | | | | | | | | | |
| (Composite | rate (%) | | | | | | | | | |
| B) | Mg content | 2.9 | 7.1 | 5.26 | 3.2 | 1.87 | 8.1 | 9.8 | 7 | |
| | (% by weight) | | | | | | | | | |
| | Si content¹⁾ | 64.1 | 64.1 | 72.1 | 66.2 | 77.1 | 63.2 | 60.6 | 58 | |
| | (% by weight) | | | | | | | | | |
| | O/Si molar | 0.80 | 0.67 | 0.47 | 0.77 | 0.45 | 0.47 | 0.46 | 1.06 | |
| | ratio | | | | | | | | | |
| | Si (220) | 9.4 | 7.51 | 7.67 | 5.6 | 6.3 | 7.4 | 15.7 | 7.6 | |
| | (nm) | | | | | | | | | |
| | Particle | 2.41 | 2.35 | 2.22 | 2.37 | 2.04 | 2.42 | 2.52 | 2.47 | |
| | density | | | | | | | | | |
| | (g/cm³) | | | | | | | | | |
| | BET (m²/g) | 31.5 | 54.8 | 263.4 | 67.6 | 274.25 | 93.1 | 102 | 18 | |

¹⁾The content of Si was a calculated value.

TABLE 3

| | | Example | | | | | | | C. Ex. | |
|---|---|---|---|---|---|---|---|---|---|---|
| | | 1 | 2 | 3 | 4 | 5 | 6 | 7 | 1 | 2 |
| Porous | Item | C1 | C3 | C4 | C8 | C9 | C10 | C11 | C15 | C16 |
| silicon- | C content | 17.8 | 16.1 | 33.1 | 30.7 | 28.7 | 27.1 | 25.5 | 5 | 5 |
| based- | (% by weight) | (CH₄ + | (CH₄ + | (CH₄ + | (CH₄ + | (CH₄ + | (C₂H₂ + | (CH₄ + | (CH₄ + | (CH₄ + |
| carbon | | Ar) | Ar | Ar) | Ar) | Ar) | Ar) | Ar) | Ar) | Ar |
| composite | Si content¹⁾ | 52.68 | 53.78 | 47.4 | 45.88 | 55.31 | 49.28 | 45.20 | 55.1 | 51.2 |
| (Composite | (% by weight) | | | | | | | | | |
| C) | Mg content | 2.38 | 5.96 | 3.52 | 2.22 | 1.33 | 4.74 | 7.3 | 6.65 | 15.2 |
| | (% by weight) | | | | | | | | | |
| | Si (220) | 10.7 | 9.63 | 7.87 | 10.9 | 9.8 | 7.5 | 15.9 | 8.8 | 18 |
| | (nm) | | | | | | | | | |
| | Mg/Si molar | 0.05 | 0.13 | 0.09 | 0.06 | 0.03 | 0.11 | 0.19 | 0.14 | 0.34 |
| | ratio | | | | | | | | | |
| | O/Si molar | 0.80 | 0.67 | 0.77 | 0.45 | 0.47 | 0.59 | 0.46 | 1.06 | 0.98 |
| | ratio | | | | | | | | | |
| | Particle | 2.36 | 2.24 | 2.05 | 1.98 | 2.1 | 2.08 | 2.47 | 2.4 | 2.53 |
| | density | | | | | | | | | |
| | (g/cm³) | | | | | | | | | |
| | D₅₀ (um) | 7.46 | 7.43 | 9.7 | 10.63 | 8.1 | 10.3 | 8.7 | 8.3 | 5.5 |
| | BET (m²/g) | 6.1 | 10.6 | 22.8 | 13 | 23.5 | 12.7 | 12.2 | 5.6 | 35.1 |

¹⁾The content of Si was a calculated value.

TABLE 4

| | | Example | | | | | | | C. Ex. | |
|---|---|---|---|---|---|---|---|---|---|---|
| | | 1 | 2 | 3 | 4 | 5 | 6 | 7 | 1 | 2 |
| Characteristics | Discharge | 1,450 | 1,490 | 1,404 | 1,673 | 1,644 | 1,516 | 1,359 | 1,410 | 1,207 |
| of secondary | capacity | | | | | | | | | |
| batteries | (mAh/g) | | | | | | | | | |
| | Initial | 80.1 | 82.8 | 83.6 | 85.1 | 84.4 | 83.7 | 87.8 | 77.5 | 83 |
| | efficiency (%) | | | | | | | | | |
| | Capacity | 78.9 | 83.9 | 89.5 | 82.3 | 86.6 | 84.4 | 82.6 | 70.1 | 73.4 |
| | retention | | | | | | | | | |
| | rate upon | | | | | | | | | |
| | 50 cycles (%) | | | | | | | | | |

As can be seen from Table 4, the secondary batteries prepared using the porous silicon-based-carbon composites of the Examples of the present invention were significantly enhanced in initial efficiency and capacity retention rate upon 50 cycles as compared with the Comparative Examples, while excellent discharge capacity was maintained.

Specifically, the secondary batteries of Examples 1 to 7 had an overall excellent discharge capacity of 1,359 mAh/g to 1,673 mAh/g, in particular, an initial efficiency of 80.1% to 87.8% and a capacity retention rate of 78.9% to 89.5% upon 50 cycles.

In contrast, the initial efficiency and the capacity retention rate upon 50 cycles of the secondary battery of Comparative Example 1 using aqua regia as an etching solution were 77.5% and 70.1%, respectively, which were significantly reduced as compared with the secondary batteries of the Examples.

In addition, in the secondary battery of Comparative Example 2 in which the molar ratio of Mg/Si exceeded 0.30 and the molar ratio of O/Si exceeded 0.90, the initial efficiency was 83%, whereas the discharge capacity and capacity retention rate upon 50 cycles were overall reduced due to the high content of magnesium.

In contrast, in the secondary batteries of Examples 1 to 7 comprising silicon particles, a magnesium compound, and carbon, in which both the molar ratio of Mg/Si and the molar ratio of O/Si satisfied the ranges of the present invention, respectively, their performance was overall excellent as compared with Comparative Examples 1 and 2. In particular, the initial efficiency and capacity retention rate were remarkably increased.

1. A porous silicon-based-carbon composite, which comprises silicon particles capable of absorbing and releasing lithium, a magnesium compound, and carbon,
wherein the molar ratio of magnesium atoms to silicon atoms (Mg/Si) present in the composite is 0.02 to 0.30, and
the molar ratio of oxygen atoms to silicon atoms (O/Si) present in the composite is 0.40 to 0.90.

2. The porous silicon-based-carbon composite of claim 1, wherein the porous silicon-based-carbon composite comprises pores inside thereof, and the porosity of the porous silicon-based-carbon composite is 1% by volume to 20% by volume based on the volume of the porous silicon-based-carbon composite.

3. The porous silicon-based-carbon composite of claim 1, wherein the magnesium compound comprises MgSiO₃ crystals, Mg₂SiO₄ crystals, or a mixture thereof.

4. The porous silicon-based-carbon composite of claim 1, wherein the magnesium compound comprises fluorine-containing magnesium compound, and the fluorine-containing magnesium compound comprises magnesium fluoride (MgF₂), magnesium fluoride silicate (MgSiF₆), or a mixture thereof.

5. The porous silicon-based-carbon composite of claim 1, wherein the content of magnesium (Mg) in the porous silicon-based-carbon composite is 0.2% by weight to 15% by weight based on the total weight of the porous silicon-based-carbon composite.

6. The porous silicon-based-carbon composite of claim 1, wherein the content of silicon (Si) in the porous silicon-based-carbon composite is 10% by weight to 90% by weight based on the total weight of the porous silicon-based-carbon composite.

7. The porous silicon-based-carbon composite of claim 1, wherein the porous silicon-based-carbon composite further comprises a silicon oxide compound, and the silicon oxide compound is SiOₓ, wherein 0.5≤x≤2.

8. The porous silicon-based-carbon composite of claim 1, wherein the silicon particles have a crystallite size of 1 nm to 20 nm when calculated from the measurement of X-ray diffraction analysis.

9. The porous silicon-based-carbon composite of claim 1, wherein the porous silicon-based-carbon composite comprises a porous silicon composite and a carbon layer on its surface,
the silicon particles and the magnesium compound are present in the porous silicon composite, and
the carbon is present on the surface of at least one selected from the group consisting of the silicon particles and the magnesium compound to form a carbon layer.

10. The porous silicon-based-carbon composite of claim 9, wherein the carbon layer comprises at least one selected from the group consisting of graphene, reduced graphene oxide, a carbon nanotube, a carbon nanofiber, and graphite.

11. The porous silicon-based-carbon composite of claim 1, wherein the content of carbon (C) is 3% by weight to 60% by weight based on the total weight of the porous silicon-based-carbon composite.

12. (canceled)

13. (canceled)

14. The porous silicon-based-carbon composite of claim 1, wherein the porous silicon-based-carbon composite has a specific gravity of 1.8 g/cm³ to 2.5 g/cm³ and a specific surface area (Brunauer-Emmett-Teller method; BET) of 2 m²/g to 60 m²/g.

15. A process for preparing the porous silicon-based-carbon composite of claim 1, which comprises:
a first step of obtaining a silicon composite oxide powder using a silicon-based raw material and a magnesium-based raw material;
a second step of etching the silicon composite oxide powder using an etching solution comprising a fluorine (F) atom-containing compound;
a third step of filtering and drying the composite obtained by the etching to obtain a porous silicon composite; and
a fourth step of forming a carbon layer on the surface of the porous silicon composite by using a chemical thermal decomposition deposition method.

16. The process for preparing the porous silicon-based-carbon composite according to claim 15, wherein, in the second step, the etching solution further comprises one or more acids selected from the group consisting of organic acids, sulfuric acid, hydrochloric acid, phosphoric acid, nitric acid, and chromic acid.

17. The process for preparing the porous silicon-based-carbon composite according to claim 15, wherein, in the second step, the silicon composite oxide powder is dispersed in a dispersion medium and then etched, and
the dispersion medium comprises at least one selected from the group consisting of water, alcohol-based compounds, ketone-based compounds, ether-based compounds, hydrocarbon-based compounds, and fatty acids.

18. The process for preparing the porous silicon-based-carbon composite according to claim 15, which further comprises, after the formation of the carbon layer in the fourth step, pulverizing or crushing and classifying the porous silicon-based-carbon composite to have an average particle diameter of 2 μm to 15 μm.

19. The process for preparing the porous silicon-based-carbon composite according to claim 15, wherein the formation of the carbon layer in the fourth step is carried out by injecting at least one selected from a compound represented by the following Formulae 1 to 3 and carrying out a reaction in a gaseous state at 400° C. to 1,200° C.:
C_{N}H_{(2N+2-A)}[OH]_{A} [Formula 1]
in Formula 1, N is an integer of 1 to 20, and A is 0 or 1,
C_{N}H_{(2N-B)} [Formula 2]
in Formula 2, N is an integer of 2 to 6, and B is 0 to 2, and
CₓH_{y}O_{z} [Formula 3]
in Formula 3, x is an integer of 1 to 20, y is an integer of 0 to 25, and z is an integer of 0 to 5.

20. A negative electrode active material, which comprises the porous silicon-based-carbon composite of claim 1.

21. The negative electrode active material of claim 20, wherein the negative electrode active material further comprises a carbon-based negative electrode material, and the content of the carbon-based negative electrode material is 30% by weight to 90% by weight based on the total weight of the negative electrode active material.

22. (canceled)

23. A lithium secondary battery, which comprises the negative electrode active material of claim 20.
